(19) United States
(12) Patent Application Publication
(10) Pub. No.: US 2016/0055868 A1
(43) Pub. Date: Feb. 25, 2016

(54) MULTIPLE-INPUT-MULTIPLE-OUTPUT SENSOR DESIGNS FOR MAGNETIC APPLICATIONS

(71) Applicant: HGST NETHERLANDS B.V., Amsterdam (NL)

(72) Inventors: Zheng Gao, San Jose, CA (US); Lijie Guan, Cupertino, CA (US); Kuok S. Ho, Emerald Hills, CA (US); Suping Song, Fremont, CA (US); Shuxia Wang, San Jose, CA (US)

(73) Assignee: HGST NETHERLANDS B.V., Amsterdam (NL)

(21) Appl. No.: 14/465,748

(22) Filed: Aug. 21, 2014

(51) Int. Cl. G11B 5/39; G01R 1/18; G01R 33/09

(52) U.S. Cl. CPC G11B 5/3912; G01R 33/093; G01R 1/18

(57) ABSTRACT

According to one embodiment, a system includes a leading magnetic shield, a first sensor structure above the leading magnetic shield, a first middle magnetic shield above the first sensor structure, a nonmagnetic spacer above the first middle magnetic shield, a second middle magnetic shield above the nonmagnetic spacer, a second sensor structure above the second middle magnetic shield, and a trailing magnetic shield above the second sensor structure. Other systems, methods, and computer program products are described in additional embodiments.

### FIELD OF THE INVENTION

The present invention relates to data storage systems, and more particularly, this invention relates to multiple-input-multiple-output (MIMO) heads having sensor structures with a reduced read gap.

### BACKGROUND

The heart of a computer is a magnetic hard disk drive (HDD) which typically includes a rotating magnetic disk, a slider that has read and write heads, a suspension arm above the rotating disk and an actuator arm that swings the suspension arm to place the read and/or write heads over selected circular tracks on the rotating disk. The suspension arm biases the slider into contact with the surface of the disk when the disk is not rotating but, when the disk rotates, air is swirled by the rotating disk adjacent an air bearing surface (ABS) of the slider causing the slider to ride on an air bearing a slight distance from the surface of the rotating disk. When the slider rides on the air bearing the write and read heads are employed for writing magnetic impressions to and reading magnetic signal fields from the rotating disk. The read and write heads are connected to processing circuitry that operates according to a computer program to implement the writing and reading functions.

The read head typically utilizes a spin valve sensor, also referred to as a giant magnetoresistive (GMR) sensor. The sensor at the ABS typically includes a barrier layer sandwiched between a pinned layer and a free layer, and an antiferromagnetic layer for pinning the magnetization of the pinned layer. The magnetization of the pinned layer is pinned perpendicular to the ABS and the magnetic moment of the free layer is located parallel to the ABS, but free to rotate in response to external magnetic fields.

The volume of information processing in the information age is increasing rapidly. In particular, it is desired that HDDs be able to store more information in their limited area and volume. A technical approach to this desire is to increase the capacity by increasing the recording density of the HDD. To achieve higher recording density, further miniaturization of recorded magnetic clusters is effective, which in turn typically requires the design of smaller and smaller components. The further miniaturization of the various components, however, presents its own set of challenges and obstacles.

The need for increasing the recording density of the HDD is pushing researchers to develop data recording systems that can read and record progressively smaller bit lengths in order to increase the density of data recorded on a magnetic medium. This has led to a push to decrease the gap thickness of a read head such as a GMR head. However, the amount by which such gap thickness can be decreased has been limited by physical limitations of sensors and also by the limitations of currently available manufacturing methods.

Therefore, there is a need for improved magnetic heads and methods of manufacture that enabling reduction of the read gap thickness while preserving the reliability of the magnetic head.

### SUMMARY

A system, according to one embodiment, includes a leading magnetic shield, a first sensor structure above the leading magnetic shield, a first middle magnetic shield above the first sensor structure, a nonmagnetic spacer above the first middle magnetic shield, a second middle magnetic shield above the nonmagnetic spacer, a second sensor structure above the second middle magnetic shield, and a trailing magnetic shield above the second sensor structure.

A system, according to another embodiment, includes a first scissor sensor structure above a leading magnetic shield, a first bias structure behind the first scissor sensor structure, a second scissor sensor structure above the first scissor sensor, and a second bias structure behind the second scissor sensor structure.

Any of these embodiments may be implemented in a magnetic data storage system such as a disk drive system, which may include a magnetic head, a drive mechanism for passing a magnetic medium (e.g., hard disk) over the magnetic head, and a controller electrically coupled to the magnetic head.

Other aspects and advantages of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the present invention, as well as the preferred mode of use, reference should be made to the following detailed description read in conjunction with the accompanying drawings.

FIG. 1 is a simplified drawing of a magnetic recording disk drive system.

FIG. 2A is a schematic representation in section of a recording medium utilizing a longitudinal recording format.

FIG. 2B is a schematic representation of a conventional magnetic recording head and recording medium combination for longitudinal recording as in FIG. 2A.

FIG. 2C is a magnetic recording medium utilizing a perpendicular recording format.

FIG. 2D is a schematic representation of a recording head and recording medium combination for perpendicular recording on one side.

FIG. 2E is a schematic representation of a recording apparatus adapted for recording separately on both sides of the medium.

FIG. 3A is a cross-sectional view of one particular embodiment of a perpendicular magnetic head with helical coils.

FIG. 3B is a cross-sectional view of one particular embodiment of a piggyback magnetic head with helical coils.

FIG. 4A is a cross-sectional view of one particular embodiment of a perpendicular magnetic head with looped coils.

FIG. 4B is a cross-sectional view of one particular embodiment of a piggyback magnetic head with looped coils.

FIG. 5 is a partial cross-sectional perspective view of a system according to one embodiment.

FIG. 6 is a partial cross-sectional perspective view of a system according to one embodiment.

FIG. 7A is a partial cross-sectional perspective view of systems according to one embodiment.

FIG. 7B is a detailed view of the embodiment of FIG. 7A taken from circle 7B.

FIG. 7C is a partial cross-sectional perspective view of a system according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified. Furthermore, as used herein, the term “about” with reference to some stated value refers to the stated value ±10% of said value.

The following description discloses several preferred embodiments of disk-based storage systems and/or related systems and methods, as well as operation and/or component parts thereof. Various embodiments described herein include MIMO heads having sensor structures with a desirably reduced read gap, as will be described in further detail below.

In one general embodiment, a system includes a leading magnetic shield, a first sensor structure above the leading magnetic shield, a first middle magnetic shield above the first sensor structure, a nonmagnetic spacer above the first middle magnetic shield, a second middle magnetic shield above the nonmagnetic spacer, a second sensor structure above the second middle magnetic shield, and a trailing magnetic shield above the second sensor structure.

In one general embodiment, a system includes a first scissor sensor structure above a leading magnetic shield, a first bias structure behind the first scissor sensor structure, a second scissor sensor structure above the first scissor sensor, and a second bias structure behind the second scissor sensor structure.

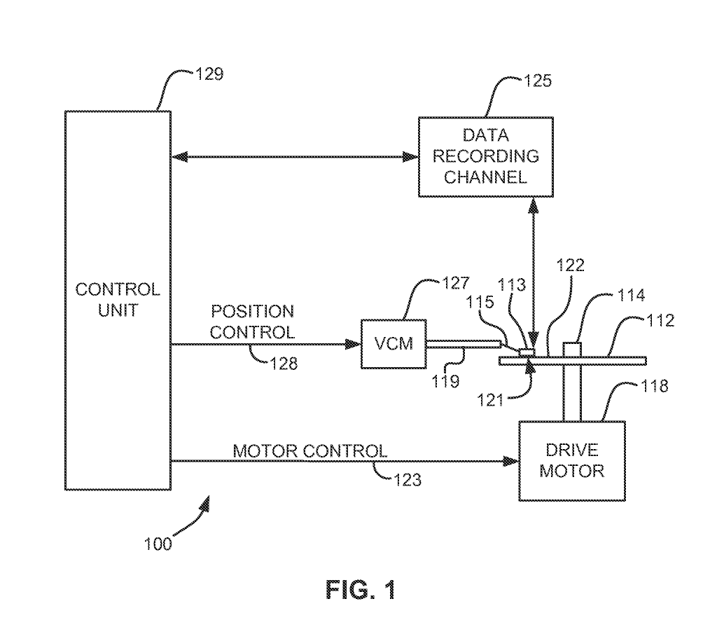

Referring now to FIG. 1, there is shown a disk drive 100 in accordance with one embodiment of the present invention. As shown in FIG. 1, at least one rotatable magnetic medium (e.g., magnetic disk) 112 is supported on a spindle 114 and rotated by a drive mechanism, which may include a disk drive motor 118. The magnetic recording on each disk is typically in the form of an annular pattern of concentric data tracks (not shown) on the disk 112. Thus, the disk drive motor 118 preferably passes the magnetic disk 112 over the magnetic read/write portions 121, described immediately below.

At least one slider 113 is positioned near the disk 112, each slider 113 supporting one or more magnetic read/write portions 121, e.g., of a magnetic head according to any of the approaches described and/or suggested herein. As the disk rotates, slider 113 is moved radially in and out over disk surface 122 so that portions 121 may access different tracks of the disk where desired data are recorded and/or to be written. Each slider 113 is attached to an actuator arm 119 by means of a suspension 115. The suspension 115 provides a slight spring force which biases slider 113 against the disk surface 122. Each actuator arm 119 is attached to an actuator 127. The actuator 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of disk 112 generates an air bearing between slider 113 and disk surface 122 which exerts an upward force or lift on the slider. The air bearing thus counter-balances the slight spring force of suspension 115 and supports slider 113 off and slightly above the disk surface by a small, substantially constant spacing during normal operation. Note that in some embodiments, the slider 113 may slide along the disk surface 122.

The various components of the disk storage system are controlled in operation by control signals generated by controller 129, such as access control signals and internal clock signals. Typically, control unit 129 comprises logic control circuits, storage (e.g., memory), and a microprocessor. In a preferred approach, the control unit 129 is electrically coupled (e.g., via wire, cable, line, etc.) to the one or more magnetic read/write portions 121, for controlling operation thereof. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Read and write signals are communicated to and from read/write portions 121 by way of recording channel 125.

The above description of a typical magnetic disk storage system, and the accompanying illustration of FIG. 1 is for representation purposes only. It should be apparent that disk storage systems may contain a large number of disks and actuators, and each actuator may support a number of sliders.

An interface may also be provided for communication between the disk drive and a host (integral or external) to send and receive the data and for controlling the operation of the disk drive and communicating the status of the disk drive to the host, as will be understood by those of skill in the art.

In a typical head, an inductive write portion includes a coil layer embedded in one or more insulation layers (insulation stack), the insulation stack being located between first and second pole piece layers. A gap is formed between the first and second pole piece layers of the write portion by a gap layer at or near a media facing surface of the head (sometimes referred to as an ABS in a disk drive). The pole piece layers may be connected at a back gap. Currents are conducted through the coil layer, which produce magnetic fields in the pole pieces. The magnetic fields fringe across the gap at the media facing surface for the purpose of writing bits of magnetic field information in tracks on moving media, such as in circular tracks on a rotating magnetic disk.

The second pole piece layer has a pole tip portion which extends from the media facing surface to a flare point and a yoke portion which extends from the flare point to the back gap. The flare point is where the second pole piece begins to widen (flare) to form the yoke. The placement of the flare point directly affects the magnitude of the magnetic field produced to write information on the recording medium.

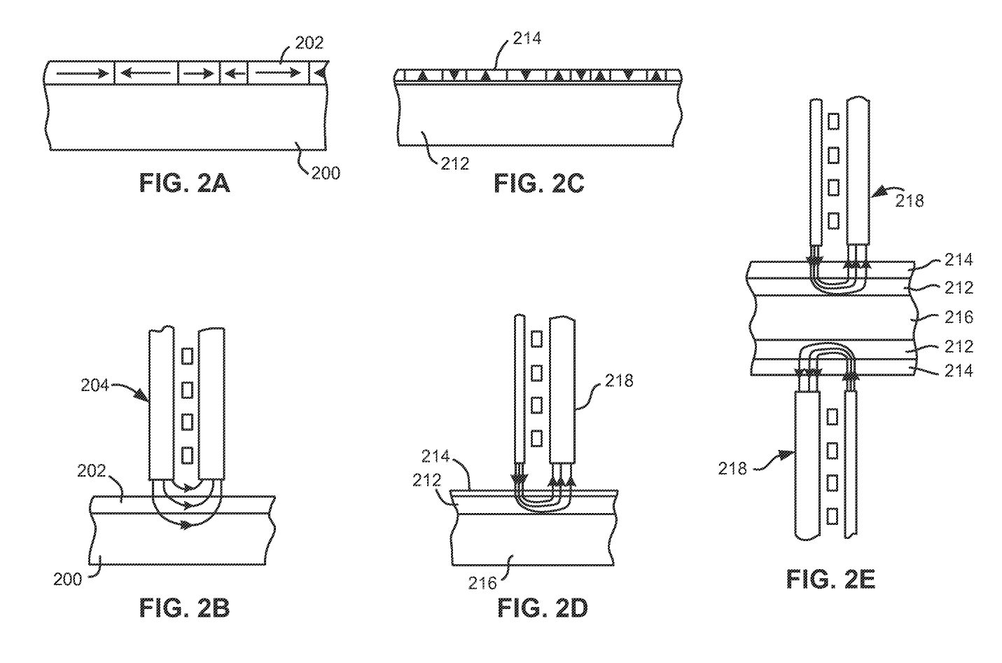

FIG. 2A illustrates, schematically, a conventional recording medium such as used with magnetic disc recording systems, such as that shown in FIG. 1. This medium is utilized for recording magnetic impulses in or parallel to the plane of the medium itself. The recording medium, a recording disc in this instance, comprises basically a supporting substrate 200 of a suitable non-magnetic material such as aluminum or glass, with an overlying coating 202 of a suitable and conventional magnetic layer.

FIG. 2B shows the operative relationship between a conventional recording/playback head 204, which may preferably be a thin film head, and a conventional recording medium, such as that of FIG. 2A.

FIG. 2C illustrates, schematically, the orientation of magnetic impulses substantially perpendicular to the surface of a recording medium as used with magnetic disc recording systems, such as that shown in FIG. 1. For such perpendicular recording the medium typically includes an under layer 212 of a material having a high magnetic permeability. This under layer 212 is then provided with an overlying coating 214 of magnetic material preferably having a high coercivity relative to the under layer 212.

FIG. 2D illustrates the operative relationship between a perpendicular head 218 and a recording medium. The recording medium illustrated in FIG. 2D includes both the high permeability under layer 212 and the overlying coating 214 of magnetic material described with respect to FIG. 2C above. However, both of these layers 212 and 214 are shown applied to a suitable substrate 216. Typically there is also an additional layer (not shown) called an “exchange-break” layer or “interlayer” between layers 212 and 214.

In this structure, the magnetic lines of flux extending between the poles of the perpendicular head 218 loop into and out of the overlying coating 214 of the recording medium with the high permeability under layer 212 of the recording medium causing the lines of flux to pass through the overlying coating 214 in a direction generally perpendicular to the surface of the medium to record information in the overlying coating 214 of magnetic material preferably having a high coercivity relative to the under layer 212 in the form of magnetic impulses having their axes of magnetization substantially perpendicular to the surface of the medium. The flux is channeled by the soft underlying coating 212 back to the return layer (P1) of the head 218.

FIG. 2E illustrates a similar structure in which the substrate 216 carries the layers 212 and 214 on each of its two opposed sides, with suitable recording heads 218 positioned adjacent the outer surface of the magnetic coating 214 on each side of the medium, allowing for recording on each side of the medium.

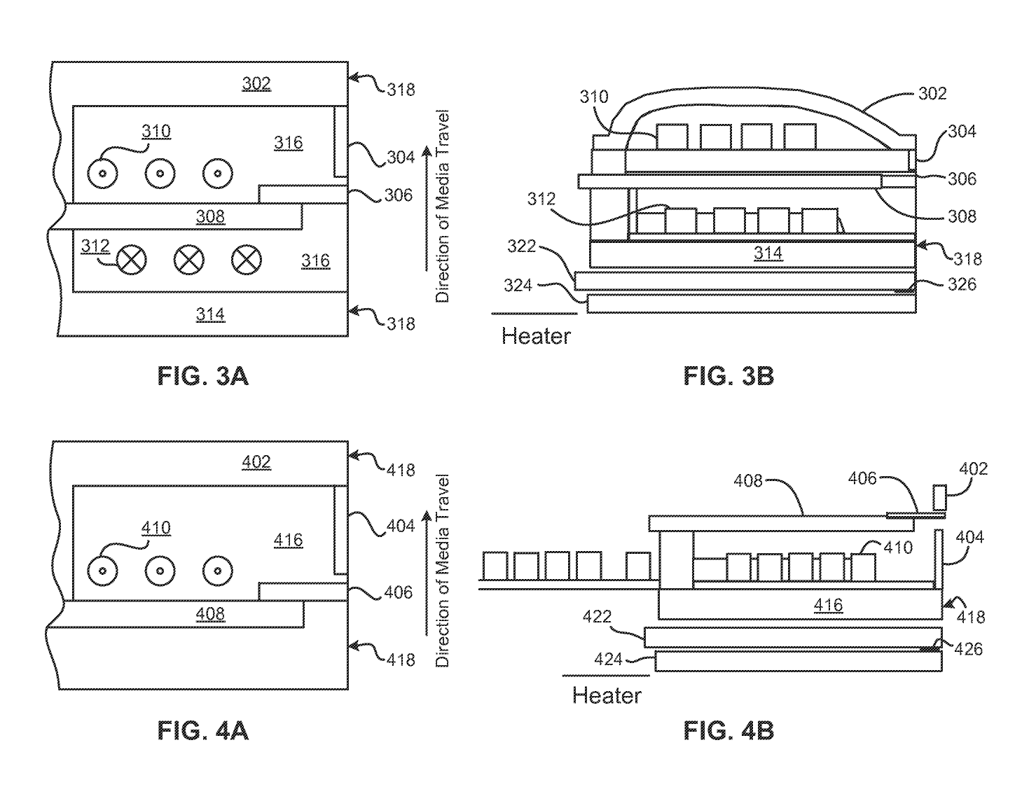

FIG. 3A is a cross-sectional view of a perpendicular magnetic head. In FIG. 3A, helical coils 310 and 312 are used to create magnetic flux in the stitch pole 308, which then delivers that flux to the main pole 306. Coils 310 indicate coils extending out from the page, while coils 312 indicate coils extending into the page. Stitch pole 308 may be recessed from the media facing surface 318. Insulation 316 surrounds the coils and may provide support for some of the elements. The direction of the media travel, as indicated by the arrow to the right of the structure, moves the media past the lower return pole 314 first, then past the stitch pole 308, main pole 306, trailing shield 304 which may be connected to the wrap around shield (not shown), and finally past the upper return pole 302. Each of these components may have a portion in contact with the media facing surface 318. The media facing surface 318 is indicated across the right side of the structure.

Perpendicular writing is achieved by forcing flux through the stitch pole 308 into the main pole 306 and then to the surface of the disk positioned towards the media facing surface 318.

FIG. 3B illustrates a piggyback magnetic head having similar features to the head of FIG. 3A. Two shields 304, 314 flank the stitch pole 308 and main pole 306. Also sensor shields 322, 324 are shown. The sensor 326 is typically positioned between the sensor shields 322, 324.

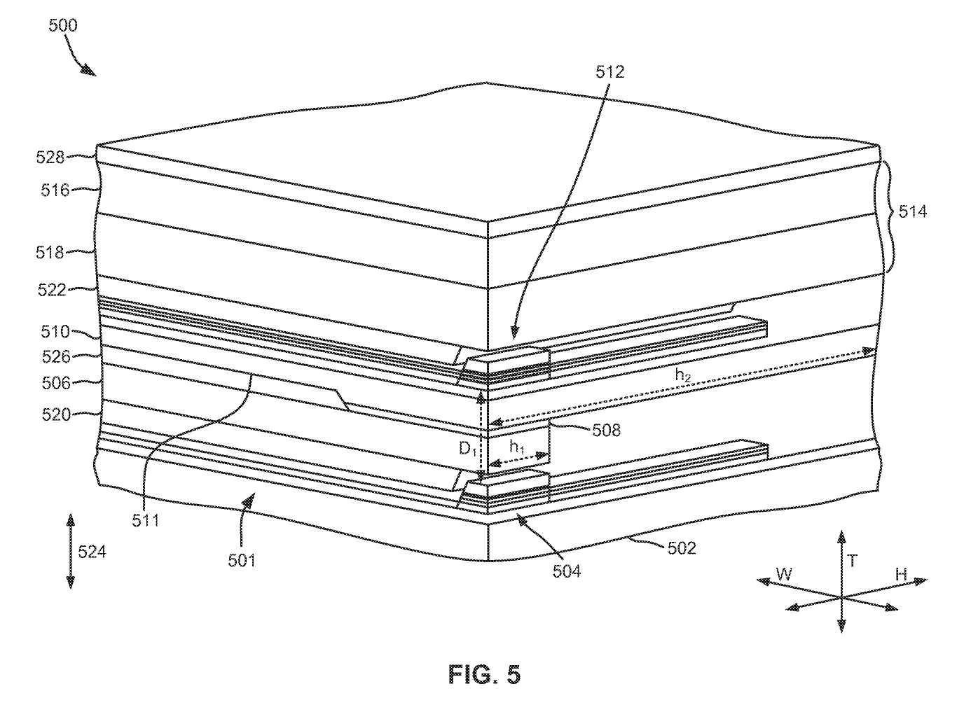

FIG. 4A is a schematic diagram of one embodiment which uses looped coils 410, sometimes referred to as a pancake configuration, to provide flux to the stitch pole 408. The stitch pole then provides this flux to the main pole 406. In this orientation, the lower return pole is optional. Insulation 416 surrounds the coils 410, and may provide support for the stitch pole 408 and main pole 406. The stitch pole may be recessed from the media facing surface 418. The direction of the media travel, as indicated by the arrow to the right of the structure, moves the media past the stitch pole 408, main pole 406, trailing shield 404 which may be connected to the wrap around shield (not shown), and finally past the upper return pole 402 (all of which may or may not have a portion in contact with the media facing surface 418). The media facing surface 418 is indicated across the right side of the structure. The trailing shield 404 may be in contact with the main pole 406 in some embodiments.

FIG. 4B illustrates another type of piggyback magnetic head having similar features to the head of FIG. 4A including a looped coil 410, which wraps around to form a pancake coil. Also, sensor shields 422, 424 are shown. The sensor 426 is typically positioned between the sensor shields 422, 424.

In FIGS. 3B and 4B, an optional heater is shown away from the media facing surface of the magnetic head. A heater (Heater) may also be included in the magnetic heads shown in FIGS. 3A and 4A. The position of this heater may vary based on design parameters such as where the protrusion is desired, coefficients of thermal expansion of the surrounding layers, etc.

Except as otherwise described herein, the various components of the structures of FIGS. 3A-4B may be of conventional materials and design, as would be understood by one skilled in the art.

As previously mentioned, the desire for increasing the recording density of HDDs is pushing researchers to develop data recording systems that can read and record progressively smaller bit lengths along the track direction in order to increase the density of data recorded on a magnetic medium. This has led to attempts to decrease the gap thickness of a read head (also referred to herein as the “read gap”). However, in conventional products, the amount by which such gap thickness can be decreased has been limited by physical limitations of sensors and also by the limitations of currently available manufacturing methods.

In sharp contrast to such conventional shortcomings, various embodiments presented herein include improved MIMO sensor structures desirably having a reduced read gap, as will be described in further detail below.

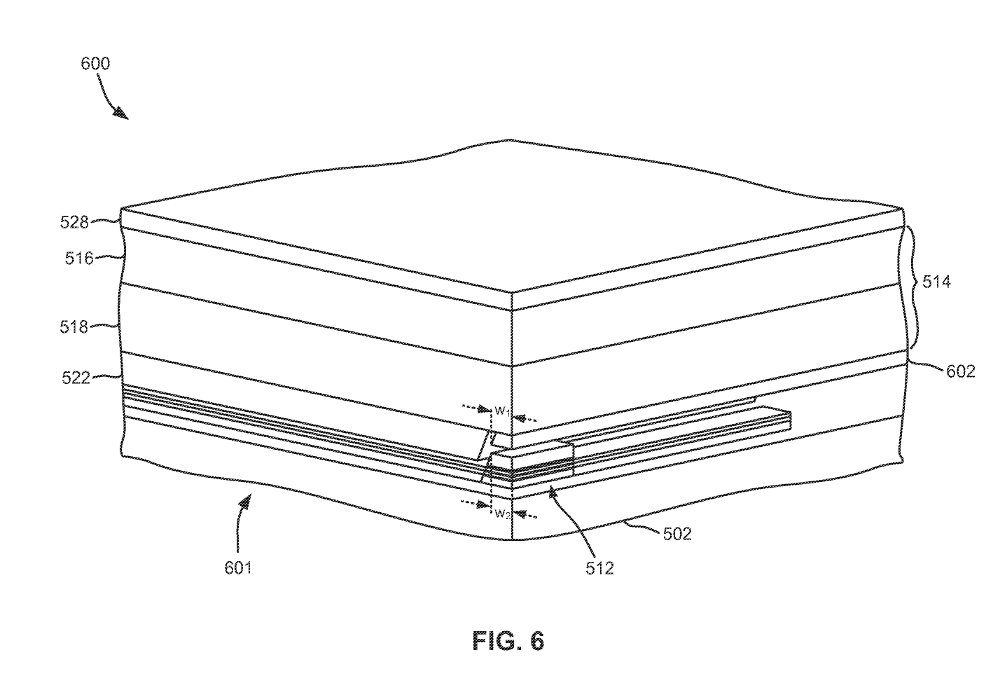

Looking to FIG. 5, a system 500 having a MIMO sensor structure is illustrated according to one embodiment. Particularly, the depiction is a partial cross-sectional view showing the media facing surface 501 of the system 500 oriented along a plane extending along the width direction W and the thickness direction T. The cross-section is taken along a plane extending along the height direction H and the thickness direction T.

As an option, the present system 500 may be implemented in conjunction with features from any other embodiment listed herein, such as those described with reference to the other FIGS. Of course, however, such system 500 and others presented herein may be used in various applications and/or in permutations which may or may not be specifically described in the illustrative embodiments listed herein. Further, the system 500 presented herein may be used in any desired environment. Thus FIG. 5 (and the other FIGS.) should be deemed to include any and all possible permutations.

Referring now to FIG. 5, system 500 includes leading magnetic shield 502 and first sensor structure 504 positioned above the leading magnetic shield 502. Moreover, a first middle magnetic shield 506 is positioned above the first sensor structure 504, and a nonmagnetic spacer 508 is positioned above the first middle magnetic shield 506. Further still, a second middle magnetic shield 510 is positioned above nonmagnetic spacer 508.

System 500 additionally includes a trailing magnetic shield 514 which is separated from the second middle magnetic shield 510 by a second sensor structure 512 which is positioned between the two. Additionally, as illustrated in the present embodiment, the trailing magnetic shield 514 may include a top portion 516 and a bottom portion 518.

According to different approaches, leading magnetic shield 502, and/or trailing magnetic shield 514 (e.g., both top and bottom portions 516, 518) may include one or more magnetically permeable material, e.g., such as Ni, Co and Fe alloys, but is in no way limited thereto. Moreover, leading and trailing magnetic shields 502, 514 may include the same, similar, or different materials, compositions, dimensions, etc., depending on the desired embodiment.

As illustrated in FIG. 5, second middle magnetic shield 510 has a longer height h₂ than the height h₁ of the first middle magnetic shield 506 measured in a direction perpendicular to the media facing surface 501 of system 500. However, in other approaches, the second middle magnetic shield 510 may have a height that is the same or shorter than that of the first middle magnetic shield 506, depending on the desired embodiment.

In further approaches, first middle magnetic shield 506 and/or second middle magnetic shield 510 may include any magnetic shield described immediately above with reference to leading and trailing magnetic shields 502, 514, or any other magnetic shield described herein. Moreover, first and second middle magnetic shields 506, 510 may include the same, similar, or different materials, compositions, dimensions, etc., depending on the desired embodiment. According to an exemplary embodiment, the first middle magnetic shield 506 may include NiFe. Furthermore, according to preferred approaches, second middle magnetic shield 510 includes one or more material having a high magnetic moment, e.g., at least higher than the magnetic moment of the first middle magnetic shield 506.

Referring still to FIG. 5, first and second sensor structures 504, 512 are preferably configured to detect magnetic transitions of a magnetic medium such as a magnetic disk. Moreover, it is desirable that first and second sensor structures 504, 512 include a tunneling magnetoresistance (TMR) sensor, but are in no way limited thereto. Depending on the desired embodiment, the first sensor structure 504 and/or second sensor structure 512 may include any type of current in plane (CIP) or current perpendicular to plane (CPP) sensor, e.g., a giant magnetoresistive (GMR) sensor, Anisotropic magnetoresistance (AMR) sensor, scissor sensor, etc., or any other type of sensor structure which would be apparent to one skilled in the art upon reading the present description.

In preferred embodiments, the first and second sensor structures 504, 512 include the same type of sensor. For example, if the first sensor structure 504 includes a TMR sensor, it is preferred that the second sensor structure 512 includes a TMR sensor as well. This allows for the system 500 to perform MIMO operations whereby the signal from both sensor structures is utilized while reading data from a given medium. Moreover, in other approaches, data from multiple data tracks may be read and processed concurrently when using sensor structures having the same type of sensor. However, first and second sensor structures 504, 512 are in no way intended to be limited to being the same type of sensor. In other embodiments, the first and second sensor structures 504, 512 may include similar (but not the same) or different types of sensors, depending on the desired embodiment.

System 500 further includes side magnetic shields 520, 522 positioned on opposite sides of the first sensor structure in a direction perpendicular to an intended direction 524 of media travel relative thereto. Depending on the desired embodiment, one or both of the side magnetic shields 520, 522 may include any of the same, similar, or different materials, compositions, dimensions, etc., as any of the magnetic shield layers described herein.

A pinning layer 526 is positioned between (e.g., adjacent) each of the side magnetic shields 520, 522. The pinning layer 526 may be used for pinning a magnetic orientation of an associated one or more of the side magnetic shields 520, 522. It follows that in some approaches, the pinning layer 526 may be an antiferromagnetic (AFM) layer, whereby the pinning layer 526 may include any materials, compositions, dimensions, etc. that would be apparent to one skilled in the art upon reading the present description. For example, the pinning layer 526 may include PtMn, IrMn, etc.

Looking still to system 500 of FIG. 5, a lower surface of the second middle magnetic shield 510 has a cutout 511 for accommodating the pinning layer 526. This results in having only a portion of the pinning layer's 526 thickness contribute to the overall distance separating the first and second sensor structures 504, 512 in an intended direction 524 of media travel relative thereto. Thus, the cutout of the second middle magnetic shield 510 allows for the distance separating the leading and trailing magnetic shields to be reduced, thereby resulting in an improved (shortened) read gap. As previously mentioned, the reduction of the read gap for a given embodiment is desired, particularly for increasing the recording density of HDDs.

Moreover, the cutout 511 of the second middle magnetic shield 510 allows for a reduced spacing between the first and second sensor structures 504, 512. As a result of the design of the components of system 500, the distance D₁ separating the first and second sensor structures 504, 512 in an intended direction 524 of media travel relative thereto may be less than about 60 nm, more preferably less than about 50 nm, but may be higher or lower depending on the desired embodiment. Thus, various embodiments described herein are able to achieve a 50% or greater reduction in the spacing between sensors compared to conventional MIMO products which have sensors separated by 120 nm or more.

In other approaches, an insulating layer (not shown) may be positioned between the first and second middle magnetic shields 506, 510, e.g., for electrically isolating the sensors. Thus, in preferred approaches, the insulating layer includes electrically insulating materials such as alumina, plastic, rubber, glass, etc., or any other electrically insulating material which would be apparent to one skilled in the art upon reading the present description. By electrically insulating the first and second middle magnetic shields 506, 510, system 500 gains the ability to provide two independent signals as each of the first and second sensor structures 504, 512 and corresponding shield layers are electrically isolated from each other. This may be useful, for example, where current in plane (CIP) sensors are used and/or in approaches where independent signals are desired. In some approaches, the nonmagnetic spacer 508 may serve as at least a portion of an electrically insulating layer, e.g., for electrically isolating the first and second middle magnetic shields 506, 510. However, in other approaches, nonmagnetic spacer 508 may include Ru, Ta, etc., or any other nonmagnetic material which would be apparent to one skilled in the art upon reading the present description.

It follows that, in some embodiments one or both of the first and second sensor structures 504, 512 may be electrically coupled to a controller, e.g., which controls operation of the sensor structures 504, 512. Thus, each of the first and second sensor structures 504, 512 may perform independent read operations concurrently with each other. In such approaches having a controller electrically coupled to one or both of the first and second sensor structures 504, 512, the controller may include any type of controller which would be apparent to one skilled in the art upon reading the present description, and may incorporate any of the approaches described and/or suggested above, e.g., see control unit 129 of FIG. 1.

Note that in the embodiment of FIG. 5 and other embodiments, additional layers of known type may be present. Such layers may include, but are not limited to seed layers, insulating layers, nonmagnetic layers, etc.

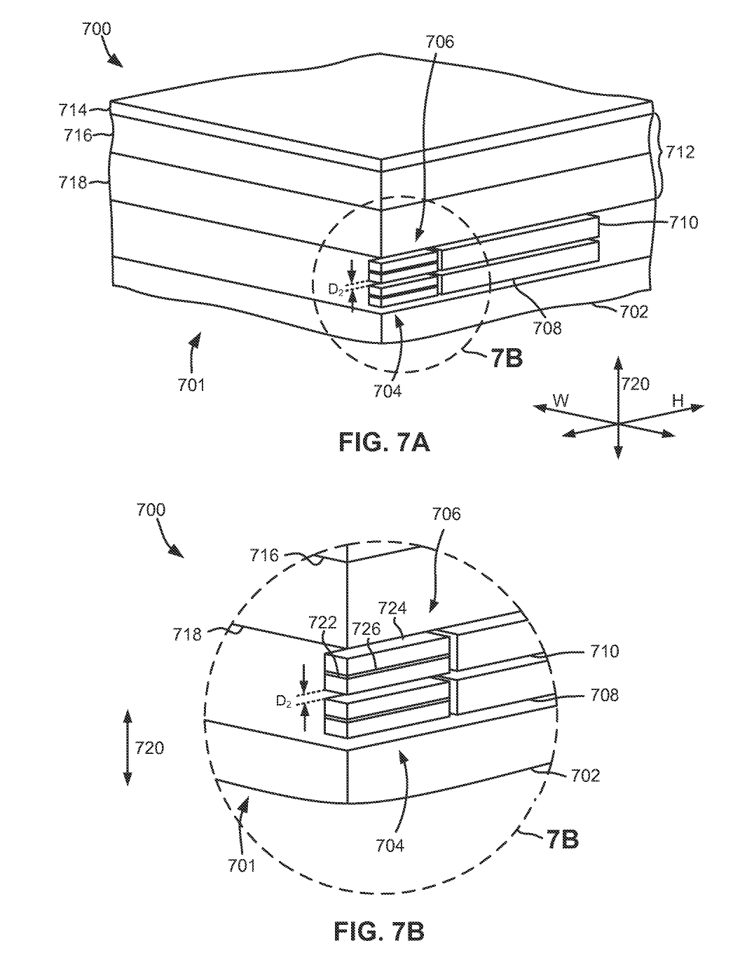

Further still, although not visible in the present illustration of FIG. 5, in some embodiments, system 500 may include a notch layer between the second sensor structure 512 and the trailing magnetic shield 514, e.g., see 602 of FIG. 6.

FIG. 6 depicts a system 600 having a notch layer 602, in accordance with one embodiment. As an option, the present system 600 may be implemented in conjunction with features from any other embodiment listed herein, such as those described with reference to the other FIGS., such as FIG. 5. Specifically, FIG. 6 illustrates variations of the embodiment of FIG. 5 and accordingly, various components of FIG. 6 have common numbering with those of FIG. 5.

Of course, however, such system 600 and others presented herein may be used in various applications and/or in permutations which may or may not be specifically described in the illustrative embodiments listed herein. Further, the system 600 presented herein may be used in any desired environment. Thus FIG. 6 (and the other FIGS.) should be deemed to include any and all possible permutations.

Referring now to FIG. 6, system 600 includes a leading magnetic shield 502, above which is a sensor structure 512 and corresponding side shield 522. Moreover, a notch layer 602 is positioned above the sensor structure 512. Furthermore, trailing magnetic shield 514 (e.g., having top and bottom portions 516, 518) and AFM layer 528 are positioned above the notch layer 602. Thus, the notch layer 602 is positioned between the sensor structure 512 and the trailing magnetic shield 514.

In preferred approaches, the notch layer 602 includes a magnetic material, e.g., NiFe. By forming the notch layer 602 using a magnetic material, the notch layer 602 effectively acts as a magnetic extension of the magnetically biased trailing magnetic shield 514. Thus, the effective read gap, e.g., separation between the leading and trailing magnetic shields 502, 514, is desirably reduced.

With continued reference to system 600 of FIG. 6, the notch layer 602 has a width (2×w₁) at a media facing surface 601 thereof no wider than a width (2×w₂) of the sensor structure 512 at a media facing surface 601 thereof.

Moreover, it should be noted that although the embodiment illustrated in FIG. 6 shows only one sensor structure 512 and corresponding side magnetic shield 522, as noted above, the notch layer 602 may be implemented in embodiments having more than one sensor structure, e.g., in systems having MIMO functionality as seen in system 500 of FIG. 5.

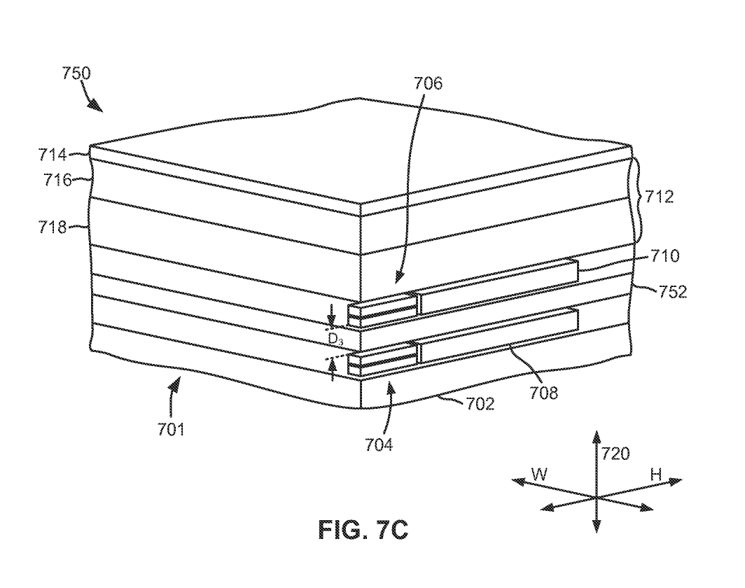

According to different embodiments, any of the approaches described herein may be implemented in systems having scissor sensors. Looking to FIGS. 7A-7C, systems 700, 750 having scissor sensors are illustrated according to two embodiments. As an option, the present systems 700, 750 may be implemented in conjunction with features from any other embodiment listed herein, such as those described with reference to the other FIGS., such as FIGS. 5-6. Of course, however, such systems 700, 750 and others presented herein may be used in various applications and/or in permutations which may or may not be specifically described in the illustrative embodiments listed herein. Further, the systems 700, 750 presented herein may be used in any desired environment. Thus FIGS. 7A-7C (and the other FIGS.) should be deemed to include any and all possible permutations.

In FIGS. 7A-7C, both systems 700, 750 include a leading shield 702, above which first and second scissor sensor structures 704, 706 and corresponding first and second bias structures 708, 710, respectively, are positioned. Moreover, trailing magnetic shield 712 and AFM layer 714 are positioned above first and second scissor sensor structures 704, 706.

As mentioned in other embodiments above, trailing magnetic shield 712 includes a top portion 716 and a bottom portion 718 which may include the same, similar, or different materials, compositions, dimensions, etc., depending on the desired embodiment.

Looking momentarily to FIG. 7B, each of the first and second scissor sensor structures 704, 706 may include a first free layer 722 separated from a second free layer 724 by a barrier layer 726. The barrier layer 726 preferably includes MgO or a conventional tunnel barrier material, but is not limited thereto. Moreover, the first and second free layers 722, 724 may be of conventional construction as would be appreciated by one skilled in the art upon reading the present description.

Furthermore, looking to the first and second bias structures 708, 710, these bias structures are positioned behind the respective first and second scissor sensor structures 704, 706 along a direction perpendicular to the media facing surface 701. In other words, the first and second scissor sensor structures 704, 706 are positioned closer to the media facing surface 701 than the first and second bias structures 708, 710 along a direction perpendicular to the media facing surface 701.

Moreover, as shown, neither system 700, 750 includes side magnetic shields adjacent either of the scissor sensor structures 704, 706. First and second rear bias structures 708, 710 are able to adequately magnetically bias the scissor sensor structures 704, 706 regardless of the presence of any side magnetic shields. Thus, in various approaches, which are in no way intended to limit the invention, some systems 700, 750 may have no side biasing layers and/or no side magnetic shields positioned in a same plane with either of the scissor sensor structures 704, 706, said plane being oriented perpendicular to a media facing surface and a direction of tape travel, i.e., along the height-width (H-W) plane. However, rear biasing structures, e.g., 708 and 710 of FIG. 7B, may be present.

Referring now specifically to FIG. 7C, system 750 includes a middle magnetic shield 752 which is positioned between the first and second scissor sensor structures 704, 706. According to different approaches, middle magnetic shield 752 may include any of the materials, compositions, dimensions, etc. described above, depending on the desired embodiment. In an exemplary embodiment, which is in no way intended to limit the invention, the middle magnetic shield 752 may include NiFe.

As a result of placing the middle magnetic shield 752 between the first and second scissor sensor structures 704, 706, the distance D₃ between the first and second scissor sensor structures 704, 706 in an intended direction 720 of media travel relative thereto, may be less than about 60 nm, more preferably less than about 50 nm, but could be higher or lower depending on the desired embodiment.

Alternatively, looking now to FIG. 7A, system 700 does not include a middle magnetic shield between the first and second scissor sensor structures 704, 706. Thus, in one approach, which is in no way intended to limit the invention, it could be said that system 700 may have a proviso that no magnetic shield is positioned between the first and second scissor sensor structures 704, 706. However, in other approaches, different layers and/or structures may be positioned between the first and second scissor sensor structures 704, 706, e.g., depending on the desired embodiment.

Compared to distance D₃ as seen in system 750, the distance D₂ of FIG. 7A between the first and second scissor sensor structures 704, 706 in an intended direction 720 of media travel relative thereto may be less than about 20 nm, but could be higher or lower.

Furthermore, in some embodiments a notch layer may be positioned between the second scissor sensor structure 706 and the trailing magnetic shield 712. As described above, the notch layer preferably includes a magnetic material, e.g., for effectively achieving a magnetic extension of the magnetically biased trailing magnetic shield 712. Thus, the effective read gap (the separation between the leading and trailing magnetic shields 702, 712) is desirably reduced.

It should be noted that methodology presented herein for at least some of the various embodiments may be implemented, in whole or in part, in computer hardware, software, by hand, using specialty equipment, etc. and combinations thereof.

Moreover, any of the structures and/or steps may be implemented using known materials and/or techniques, as would become apparent to one skilled in the art upon reading the present specification.

The inventive concepts disclosed herein have been presented by way of example to illustrate the myriad features thereof in a plurality of illustrative scenarios, embodiments, and/or implementations. It should be appreciated that the concepts generally disclosed are to be considered as modular, and may be implemented in any combination, permutation, or synthesis thereof. In addition, any modification, alteration, or equivalent of the presently disclosed features, functions, and concepts that would be appreciated by a person having ordinary skill in the art upon reading the instant descriptions should also be considered within the scope of this disclosure.

While various embodiments have been described above, it should be understood that they have been presented by way of example only, and not limitation. Thus, the breadth and scope of an embodiment of the present invention should not be limited by any of the above-described exemplary embodiments, but should be defined only in accordance with the following claims and their equivalents.

What is claimed is:

1. A system, comprising:
a leading magnetic shield;
a first sensor structure above the leading magnetic shield;
a first middle magnetic shield above the first sensor structure;
a nonmagnetic spacer above the first middle magnetic shield;
a second middle magnetic shield above the nonmagnetic spacer;
a second sensor structure above the second middle magnetic shield;
a trailing magnetic shield above the second sensor structure.

2. The system as recited in claim 1, wherein a distance between the first and second sensor structures in an intended direction of media travel relative thereto is less than about 60 nm.

3. The system as recited in claim 1, wherein a distance between the first and second sensor structures in an intended direction of media travel relative thereto is less than 50 nm.

4. The system as recited in claim 1, comprising side magnetic shields positioned on opposite sides of the first sensor structure in a direction perpendicular to an intended direction of media travel relative thereto; and a pinning layer adjacent each of the side magnetic shields for pinning a magnetic orientation of an associated one of the side magnetic shields.

5. The system as recited in claim 4, wherein a lower surface of the second middle magnetic shield has a cutout for accommodating the pinning layer.

6. The system as recited in claim 1, comprising an insulating layer between the first middle magnetic shield and the second middle magnetic shield.

7. The system as recited in claim 1, comprising a notch layer between the second sensor structure and the trailing magnetic shield, the notch layer comprising a magnetic material.

8. The system as recited in claim 7, wherein the notch layer has a width at a media facing surface thereof no wider than the second sensor structure at a media facing surface thereof.

9. The system as recited in claim 1, wherein the second middle magnetic shield has a longer height than the first middle magnetic shield.

10. The system as recited in claim 1, further comprising:
a magnetic medium;
a drive mechanism for passing the magnetic medium over the sensor structures; and
a controller electrically coupled to the sensor structures for controlling operation thereof.

11. A system, comprising:
a first scissor sensor structure above a leading magnetic shield;
a first bias structure behind the first scissor sensor structure;
a second scissor sensor structure above the first scissor sensor, and
a second bias structure behind the second scissor sensor structure.

12. The system as recited in claim 11, wherein a distance between the first and second scissor sensor structures in an intended direction of media travel relative thereto is less than about 60 nm.

13. The system as recited in claim 11, wherein a distance between the first and second scissor sensor structures in an intended direction of media travel relative thereto is less than 50 nm.

14. The system as recited in claim 11, comprising a middle magnetic shield between the first and second scissor sensor structures.

15. The system as recited in claim 11, with a proviso that no magnetic shield is positioned between the first and second scissor sensor structures.

16. The system as recited in claim 15, wherein a distance between the first and second scissor sensor structures in an intended direction of media travel relative thereto is less than about 20 nm.

17. The system as recited in claim 11, with a proviso that no side biasing layers are positioned in a same plane with either of the scissor sensor structures, said plane being oriented perpendicular to a media facing surface and a direction of tape travel.

18. The system as recited in claim 11, with a proviso that no side magnetic shields are positioned in a same plane with either of the scissor sensor structures, said plane being oriented perpendicular to a media facing surface and a direction of tape travel.

19. The system as recited in claim 11, comprising a notch layer between the second scissor sensor structure and a trailing magnetic shield, the notch layer comprising a magnetic material.

20. The system as recited in claim 11, further comprising:
a magnetic medium;
a drive mechanism for passing the magnetic medium over the sensor structures; and
a controller electrically coupled to the sensor structures for controlling operation thereof.
